(19) United States
(12) Patent Application Publication
(10) Pub. No.: US 2013/0168718 A1
(43) Pub. Date: Jul. 4, 2013

(54) SEMICONDUCTOR LIGHT EMITTING DEVICE AND LED MODULE

(71) Applicant: SAMSUNG ELECTRONICS CO., LTD., Suwon-si (KR)

(72) Inventors: Young Chul SHIN, Seoul (KR); Hyung Duk KO, Seoul (KR)

(73) Assignee: SAMSUNG ELECTRONICS CO., LTD., Suwon-si (KR)

(21) Appl. No.: 13/731,472

(22) Filed: Dec. 31, 2012

(30) Foreign Application Priority Data
Dec. 29, 2011 (KR) 10-2011-0145795

(51) Int. Cl. H01L 33/60

(52) U.S. Cl. CPC H01L 33/60
USPC 257/98

(57) ABSTRACT

A semiconductor light emitting device includes a semiconductor laminate including first and second conductivity-type semiconductor layers and an active layer formed therebetween, and divided into first and second regions. At least one contact hole is formed on the first region and connected to a portion of the first conductivity-type semiconductor layer through the active layer. A first electrode is formed to be connected to the first conductivity-type semiconductor layer of the first region and connected to the second conductivity-type semiconductor layer of the second region through the at least one contact hole. A second electrode is formed and connected to the second conductivity-type semiconductor layer of the first region. First and second electrode pads and a support substrate are formed.

### CROSS-REFERENCE TO RELATED APPLICATION

This application claims the priority to Korean Patent Application No. 10-2011-0145795 filed on Dec. 29, 2011, in the Korean Intellectual Property Office, the disclosure of which is incorporated herein by reference.

### FIELD

The present inventive concept relates to a light emitting device and, more particularly, to a semiconductor light emitting device having a protection diode incorporated therein to protect against an electrical discharge from a source such as static electricity, or the like, a method of making the semiconductor light emitting device and a module employing the same.

### BACKGROUND

Due to the advantageous reliability, efficiency, and output of semiconductor light emitting devices, these light sources have been extensively studied and developed as high output, high efficiency light sources that may be used in the backlight of a display device or in an illumination device.

A semiconductor light emitting device generally includes a p-type semiconductor, an n-type semiconductor, and an active layer disposed between the p-type and n-type semiconductors and emitting light according to electron-hole recombination. Semiconductor light emitting devices may be classified depending on electrode positions for semiconductor layers or a current path. The type of semiconductor light emitting device may be determined depending on whether or not the substrate used in the semiconductor light emitting device has electrical conductivity. However, the present disclosure is not limited thereto.

For example, when a substrate having electrical insulation is used, mesa etching may be required to form an n-type electrode connected to an n-type semiconductor layer. Namely, portions of a p-type semiconductor layer and an active layer are removed such that a portion of the n-type semiconductor layer is exposed, and a p-type electrode and an n-type electrode are formed on an upper surface of the p-type semiconductor layer and the n-type semiconductor layer, respectively.

In such an electrode structure, a light emission area is reduced due to the mesa etching and current flow is formed in a lateral direction, making it difficult to achieve uniform current spreading, and accordingly, luminance efficiency may be reduced.

In comparison, when a conductive substrate is used, the conductive substrate may be used as an electrode part on one side. In a semiconductor light emitting device having this structure, a light emission area is not lost and a relatively uniform current flow is maintained in comparison to the foregoing structure, such that luminance efficiency may be improved.

However, when a light emitting device is implemented with a large area for a high output, an electrode structure such as an electrode finger is provided to seek uniform current spreading over the entire light emission area, and in this case, light extraction is limited by an electrode provided on a light emission surface or light is absorbed by the electrode, reducing luminance efficiency.

Also, while the semiconductor light emitting device is handled or used, it may be instantly exposed to a high voltage from a source such as an electrostatic discharge (ESD), possibly damaging the functionality of the semiconductor light emitting diode.

Thus, a scheme of additionally mounting a protection diode in a semiconductor light emitting device has been considered. However, packaging and disposing a diode in a single package space may be difficult and serve as an obstacle in manufacturing.

### SUMMARY

In the art, there is a need for a novel semiconductor light emitting device having a structure integrated with an electrostatic discharge (ESD) protection diode, and an LED module.

An aspect of the present disclosure provides a semiconductor light emitting device including a semiconductor laminate having a first main surface provided by a first conductivity-type semiconductor layer and a second main surface provided by a second conductivity-type semiconductor layer. The first and second main surfaces are opposed to each other, an active layer is formed between the first and second conductivity-type semiconductor layers, and the laminate is divided into first and second regions by a separation groove. At least one contact hole is connected to a portion of the first conductivity-type semiconductor layer through the active layer from the second main surface of the first region. A first electrode disposed on the second main surface of the semiconductor laminate is connected to the first conductivity-type semiconductor layer of the first region through the at least one contact hole and connected to the second conductivity-type semiconductor layer of the second region. A second electrode is disposed on the second main surface of the first region and connected to the second conductivity-type semiconductor layer of the first region. A first electrode pad is electrically connected to the first conductivity-type semiconductor layer of the second region. A second electrode pad is electrically connected to the second electrode, and a support substrate having electrical conductivity is disposed on the second main surface of the semiconductor laminate so as to be electrically connected to the first electrode.

The semiconductor light emitting device may further include an insulating separation layer disposed on the second main surface of the semiconductor laminate to separate the first electrode and the second electrode.

The insulating separation layer may extend between inner side walls of the contact hole and a portion of the first electrode charged in the contact hole.

The support substrate may be formed through a plating process or a wafer bonding process.

The semiconductor light emitting device may further include a passivation layer formed on lateral surfaces of the first and second regions of the semiconductor laminate.

The first electrode may include a highly reflective ohmic-contact layer. In this case, the highly reflective ohmic-contact layer may include a material selected from the group consisting of silver (Ag), nickel (Ni), aluminum (Al), rhodium (Rh), palladium (Pd), iridium (Ir), ruthenium (Ru), magnesium (Mg), zinc (Zn), platinum (Pt), gold (Au), and a combination thereof.

The at least one contact hole may be a plurality of contact holes. The first region of the semiconductor laminate may have an area larger than that of the second region of the semiconductor laminate. In this case, the second region of the semiconductor laminate may have an area equal to 20% or less of the entire area of the semiconductor laminate.

Another aspect provides a light emitting diode (LED) module including a semiconductor light emitting device, and a package substrate having first and second electrode structures.

The semiconductor light emitting device may include a semiconductor laminate having a first main surface provided by a first conductivity-type semiconductor layer and a second main surface provided by a second conductivity-type semiconductor layer. The first and second main surfaces are opposed to each other. An active layer is disposed between the first and second conductivity-type semiconductor layers, and the laminate is divided into first and second regions by a separation groove. At least one contact hole is connected to a portion of the first conductivity-type semiconductor layer through the active layer from the second main surface of the first region. A first electrode is disposed on the second main surface of the semiconductor laminate is connected to the first conductivity-type semiconductor layer of the first region through the at least one contact hole and connected to the second conductivity-type semiconductor layer of the second region. A second electrode is disposed on the second main surface of the first region and is connected to the second conductivity-type semiconductor layer of the first region. A first electrode pad electrically is connected to the first conductivity-type semiconductor layer of the second region. A second electrode pad is electrically connected to the second electrode, and a support substrate having electrical conductivity is disposed on the second main surface of the semiconductor laminate so as to be electrically connected to the first electrode.

The first electrode structure may be connected to the support substrate of the semiconductor light emitting device and the second electrode structure may be connected to the first and second electrodes of the semiconductor light emitting device, respectively. Another aspect provides a semiconductor light emitting device comprising a semiconductor laminate having first and second conductivity-type semiconductor layers and an active layer disposed between the first and second conductivity-type semiconductor layers. The laminate is divided into first and second regions by a separation groove. At least one contact hole is connected to a portion of the first conductivity-type semiconductor layer through the active layer from a bottom surface of the second conductivity-type semiconductor layer of the first region. A first electrode is disposed on the bottom surface of the second conductivity-type semiconductor layer, extending to the first conductivity-type semiconductor layer of the first region through the at least one contact hole and connected to the second conductivity-type semiconductor layer of the second region. A second electrode is disposed on the bottom surface of the second conductivity-type semiconductor layer of the first region and is connected to the second conductivity-type semiconductor layer of the first region. A first electrode pad is electrically connected to the first conductivity-type semiconductor layer of the second region. A second electrode pad is electrically connected to the second electrode, and a support substrate having electrical conductivity is disposed on the bottom surface of the second conductivity type semiconductor layer so as to be electrically connected to the first electrode.

### BRIEF DESCRIPTION OF THE DRAWINGS

FIG. 1 is a plan view of a semiconductor light emitting device according to an embodiment of the present disclosure;

FIG. 2 is a cross-sectional view of the semiconductor light emitting device illustrated in FIG. 1 taken along line I-I′;

FIG. 3 is a cross-sectional view of the semiconductor light emitting device illustrated in FIG. 1 taken along line II-II′;

FIG. 4 is a cross-sectional view of the semiconductor light emitting device illustrated in FIG. 1 taken along line III-III′;

FIG. 5 is an equivalent circuit diagram illustrating the semiconductor light emitting device illustrated in FIG. 1;

FIG. 6 is a plan view of an LED module employing a semiconductor light emitting device according to an embodiment of the present disclosure; and

FIG. 7 is an equivalent circuit diagram illustrating the LED module of FIG. 6.

### DETAILED DESCRIPTION OF THE PREFERRED EMBODIMENT

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

Examples of the present disclosure will now be described in detail with reference to the accompanying drawings. The inventive concept may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like components.

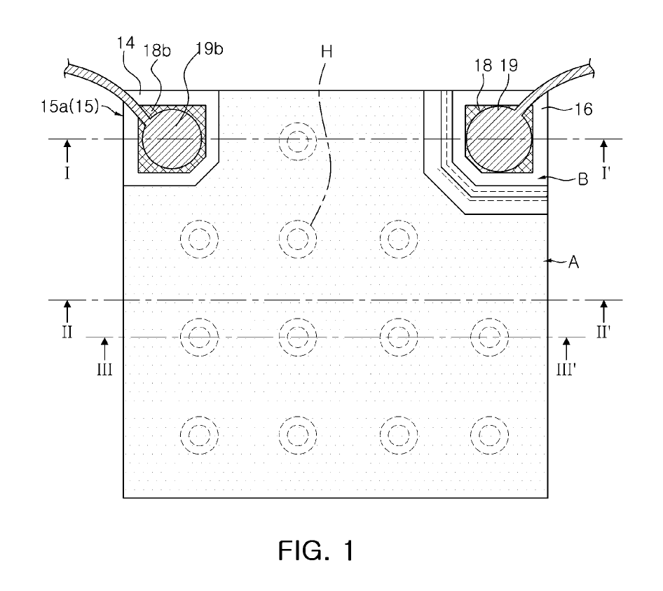

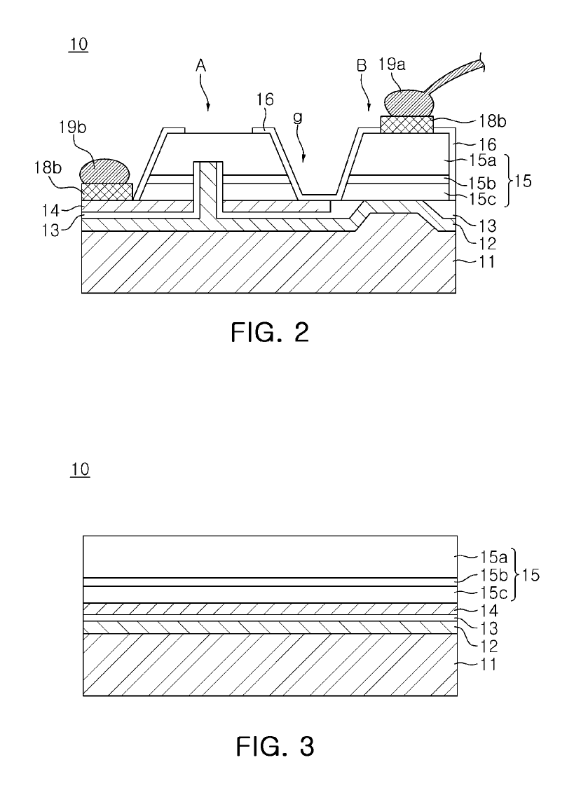

FIG. 1 is a plan view of a semiconductor light emitting device according to an embodiment of the present disclosure, and FIG. 2 is a cross-sectional view of the semiconductor light emitting device illustrated in FIG. 1 taken along line I-I′.

With reference to FIGS. 1 and 2, a semiconductor light emitting device 10 includes a semiconductor laminate (i.e., a laminated semiconductor body) 15 including first and second conductivity-type semiconductor layers 15a and 15c and an active layer 15b interposed therebetween.

The semiconductor laminate 15 has first and second main surfaces provided by the first and second conductivity-type semiconductor layers and positioned on opposite sides thereof.

The semiconductor laminate 15 may be a Group III-VI compound semiconductor such as a nitride semiconductor, but the present disclosure is not limited thereto. In the present embodiment, the first conductivity-type semiconductor layer 15a, the active layer 15b, and the second conductivity-type semiconductor layer 15c of the semiconductor laminate 15 are sequentially grown on a growth substrate, a wiring structure is formed on the first surface of the semiconductor laminate 15, and then, a support substrate 11 is employed.

Here, the support substrate 11 employed in the present embodiment may be a substrate having electrical conductivity. The support substrate 11 may be easily provided through a plating process or a wafer bonding process. Thereafter, the growth substrate is eliminated from the semiconductor laminate 15 to obtain the device structure illustrated in FIG. 1. In a general case, the first and second conductivity-type semiconductor layers 15a and 15c may be n-type and p-type semiconductor layers.

As shown in FIG. 2, the semiconductor light emitting device may further include a passivation layer 16 made of an insulation material formed on at least a lateral surface of the semiconductor laminate 15.

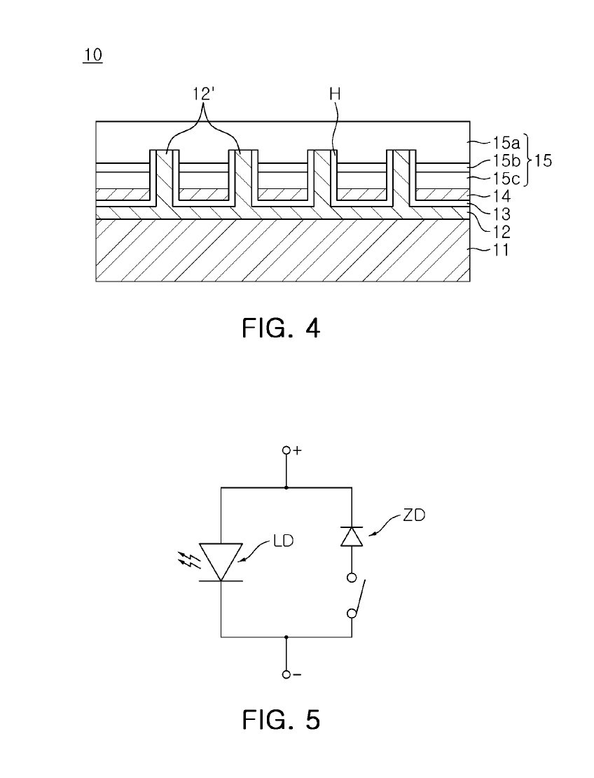

The structure of the semiconductor light emitting device 10 may be better understood with reference to the cross-sectional views of FIGS. 3 and 4. FIG. 3 is a side cross-sectional view of the semiconductor light emitting device 10 illustrated in FIG. 1 taken along line II-II′, and FIG. 4 shows a side cross-sectional view of the semiconductor light emitting device 10 illustrated in FIG. 1 taken along line III-III′.

As shown in FIG. 3, the cross-section of the semiconductor light emitting device 10 taken along line II-II′ has a structure in which a first electrode 12, an insulating separation layer 13, a second electrode 14, and the semiconductor laminate 15 are sequentially laminated on the support substrate 11 having electrical conductivity.

Meanwhile, as shown in FIG. 4, similar to the structure of FIG. 3, except for the regions in which holes H are formed, the cross-section of the semiconductor light emitting device 10 taken along line III-III′ has a structure in which the first electrode 12, the insulating separation layer 13, the second electrode 14, and the semiconductor laminate 15 are sequentially laminated on the support substrate 11.

The plurality of contact holes H are formed to be connected to the first conductivity-type semiconductor layer 15a through the second main surface of the semiconductor laminate 15. The insulating separation layer may be formed on the second main surface of the semiconductor laminate 15 to insulate the first electrode and the second electrode 14. Also, the insulating separation layer 13 may be extend to be formed on an internal lateral surface of each of the contact holes H to electrically insulate the second conductivity-type semiconductor layer 15c and the active layer 15b.

Since the plurality of contact holes H are arranged at regular intervals to allow for uniform current spreading, the first electrode 12 may be directly connected to the first conductivity-type semiconductor layer 15a. The structure in relation to the contact holes H will be described in detail hereinafter.

The semiconductor laminate 15 may be divided into a first region A and a second region B by a separation groove g. The first region A may be provided as a light emitting diode (LED) part driven like an LED, and the second region B may be provided as an ESD protection diode part.

In the present embodiment, the second region B may be provided as a bonding region for bonding a wire connected to an external circuit. The semiconductor laminate 15 divided into the two regions A and B may be operated as the LED part and the ESD protection diode part through wiring connections as follows.

In the present embodiment, the second electrode 14 is formed on the second main surface of the semiconductor laminate 15 so as to be connected to the second conductivity-type semiconductor layer 15c of the first region A.

The second electrode 14 may be a highly reflective ohmic-contact layer reflecting light generated from the active layer 15b. For example, the highly reflective ohmic-contact layer may be a material selected from the group consisting of silver (Ag), nickel (Ni), aluminum (Al), rhodium (Rh), palladium (Pd), iridium (Ir), ruthenium (Ru), magnesium (Mg), zinc (Zn), platinum (Pt), gold (Au), and a combination thereof.

The first electrode 12 connected to the first conductivity-type semiconductor layer 15a of the first region A is provided on the second main surface of the semiconductor laminate 15. As in the present embodiment, connecting of the first electrode 12 and the first conductivity-type semiconductor layer 15a of the first region A may be realized by the contact hole H.

As shown in FIG. 2, in the first region A of the semiconductor laminate 15, at least one contact hole H is formed to extend from the second main surface of the semiconductor laminate 15 and pass through the second conductivity-type semiconductor layer 15c and the active layer 15b so as to be connected to a portion of the first conductivity-type semiconductor layer 15a. A portion of the first conductivity-type semiconductor layer 15a may be exposed by the contact hole H.

The first electrode 12 may be connected to the exposed region of the first conductivity-type semiconductor layer 15a provided through the contact hole H, by the electrode part 12′ extending from the first electrode 12. Accordingly, the first electrode 12 may be electrically connected to the first conductivity-type semiconductor layer 15a even in the case that it is positioned on the second main surface.

The contact hole H may be formed after the semiconductor laminate 15 is formed on the growth substrate and before a wiring structure is formed. In the present embodiment, the contact hole H is illustrated in the form of a via, but it may be variably implemented as long as it can expose a portion of the first conductivity-type semiconductor layer 15a.

In the present embodiment, as shown in FIG. 1, a plurality of contact holes H are formed such that they are positioned over the entire area of the first region A. Since the plurality of contact holes H are formed over the large area, uniform current spreading can be promoted. This can be advantageously employed in a large semiconductor light emitting device for a high output.

As described above, the insulating separation layer 13 may be formed to easily electrically separate the first electrode 12 and the second electrode 14 provided on the second main surface of the semiconductor laminate 15. The insulating separation layer 13 may extend between inner side walls of the contact hole H and the electrode part 12′ of the first electrode 12.

The first electrode 12 may also be electrically connected to the second conductivity-type semiconductor layer 15c of the second region B, as well as to the first conductivity-type semiconductor layer 15a of the first region A. Meanwhile, the second electrode 14 connected to the second conductivity-type semiconductor layer 15c of the first region A is electrically connected to the first conductivity-type semiconductor layer 15a of the second region B.

The semiconductor light emitting device 10 according to the present embodiment includes a first electrode pad 18a electrically connected to the first conductivity-type semiconductor layer 15a of the second region B and a second electrode pad 18b electrically connected to the second electrode 14.

As shown in FIGS. 1 and 2, the first electrode pad 18a may be formed on the second region B of the semiconductor laminate 15. The second electrode 14 has a portion extending to the outside. The second electrode pad 18b may be formed on the portion extending from the second electrode 14. Conductive bumps 19a and 19b may be formed on the first and second electrode pads 18a and 18b such that they are connected by wires, respectively.

Also, as described above, the support substrate 11 employed in the present embodiment is a substrate having electrical conductivity. As shown in FIG. 2, the support substrate 11 may be electrically separated from the second electrode 14 by the insulating separation layer 13 and connected to the first electrode 12 so as to be provided as an electrode structure for the first conductivity-type semiconductor layer 15a, together with the first electrode 12. Namely, when the semiconductor light emitting device 10 is mounted, the conductive support substrate 11 may be connected to an external circuit positioned on a mounting surface thereof.

In this manner, the first electrode 12 is connected to the first conductivity-type semiconductor layer 15a of the LED part as the first region A and the second conductivity-type semiconductor layer 15c of the protection diode part as the second region B, respectively, and connecting of the first electrode 12 and an external circuit may be implemented through the support substrate 11 positioned on the second main surface.

In the present embodiment, the first and second electrode pads 18a and 18b serve as external terminals for the semiconductor light emitting device 10 together with the support substrate 11.

In detail, mutually opposite polarities of the LED part as the first region A and the protection diode part as the second region B are connected to the support substrate 11. A different polarity of the LED part is connected to the second electrode pad 18b, and a different polarity of the protection diode part is connected to the first electrode pad 18a.

In this manner, the support substrate 11 is provided as a common external terminal of the LED part as the first region A and the protection diode part as the second region B. The different polarities of the LED part and the protection diode part are connected to the first and second electrode pads 18a and 18b, respectively, such that they are separated.

In the present embodiment, a connection of the LED part LD and the protection diode part ZD may be represented by an equivalent circuit illustrated in FIG. 5.

As shown in FIG. 5, by providing the first and second electrode pads 18a and 18b, the LED part LD can separate the protection diode part ZD by circuitry.

In comparison, in case of a complete connection by circuitry, namely, when the first and second electrode pads 18a and 18b are implemented as a single pad, influence of the protection diode part ZD on electrical characteristics of the LED part LD in a forward voltage is not significant, but in a reverse voltage, only the characteristics of the protection diode part ZD, not the LED part LD, are measured, making it impossible to properly measure the electrical characteristics of the LED part LD. However, in the light emitting device illustrated in FIG. 2, the electrical characteristics of the LED part LD can be independently measured to be evaluated by using an electrical connection structure through the second electrode pad 18b and the support substrate 11.

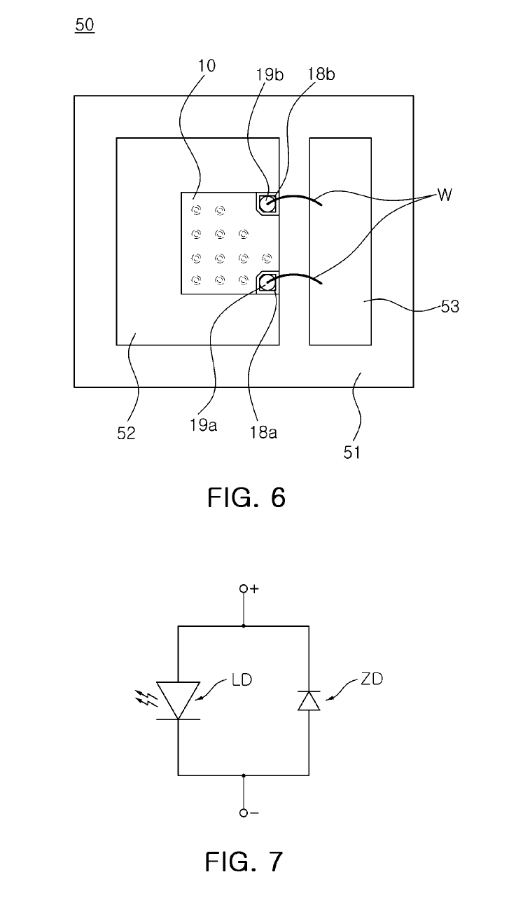

As shown in FIG. 6, the semiconductor light emitting device 10 according to the present embodiment may be implemented as a protection diode-integrated light emitting device in an LED module.

Namely, as shown in FIG. 6, an LED module 60 includes a package substrate 51 having first and second electrode structures 52 and 53 and the semiconductor light emitting device 10 illustrated in FIG. 2. As shown in FIG. 6, in the LED module 50, wires W extending from the first and second electrode pads 18a and 18b of the semiconductor light emitting device 10 may be connected to the second electrode structure 53 together.

Thus, the LED part as the first region A of the semiconductor light emitting device 10 and the protection diode part as the second region B may be connected like an equivalent circuit illustrated in FIG. 7, and accordingly, the first region A may be operated as the LED part LD and the second region B may be operated as the ESD protection diode part ZD.

In the equivalent circuit illustrated in FIG. 7, when the LED part LD is normally operated, the ESD protection diode part ZD is not electrically connected due to a reverse voltage applied thereto. However, when an instant high voltage (e.g., static electricity or a surge voltage) is generated, a current exceeding a breakdown voltage flows, and in this process, an overcurrent is induced to the ESD protection diode part ZD, thus protecting the LED part LD.

Since the first region A of the semiconductor laminate 15 is provided as a light emission region, the first region A preferably has an area larger than that of the second region B provided as the protection diode part and bonding region. Preferably, the second region B of the semiconductor laminate 15 has an area equal to 20% or less of the entire area of the semiconductor laminate 15.

As set forth above, according to the examples, the LED can be integrally implemented with the ESD protection diode, and effective luminance efficiency can be improved by increasing a light emission area. In addition, since a plurality of contact holes are employed and distributed to appropriate positions, high current spreading efficiency can be obtained even in a large area.

Electrical characteristics of the integrated LED and ESD protection diode can be individually measured.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

What is claimed is:

1. A semiconductor light emitting device comprising:
a semiconductor laminate having first and second conductivity-type semiconductor layers and an active layer disposed between the first and second conductivity-type semiconductor layers, and being divided into first and second regions by a separation groove;
at least one contact hole connected to a portion of the first conductivity-type semiconductor layer through the active layer from a bottom surface of the second conductivity-type semiconductor layer of the first region;
a first electrode formed on the bottom surface of the second conductivity-type semiconductor layer, extending to the first conductivity-type semiconductor layer of the first region through the at least one contact hole and connected to the second conductivity-type semiconductor layer of the second region;
a second electrode formed on the bottom surface of the second conductivity-type semiconductor layer of the first region and connected to the second conductivity-type semiconductor layer of the first region;
a first electrode pad electrically connected to the first conductivity-type semiconductor layer of the second region;
a second electrode pad electrically connected to the second electrode; and
a support substrate having electrical conductivity formed on the bottom surface of the second conductivity type semiconductor layer so as to be electrically connected to the first electrode.

2. The semiconductor light emitting device of claim 1, further comprising an insulating separation layer formed on the bottom surface of the semiconductor laminate to separate the first electrode and the second electrode.

3. The semiconductor light emitting device of claim 2, wherein the insulating separation layer extends between inner side walls of the contact hole and a portion of the first electrode charged in the contact hole.

4. The semiconductor light emitting device of claim 1, wherein the support substrate is formed through a plating process or a wafer bonding process.

5. The semiconductor light emitting device of claim 1, further comprising a passivation layer formed on lateral surfaces of the first and second regions of the semiconductor laminate.

6. The semiconductor light emitting device of claim 1, wherein the first electrode includes a highly reflective ohmic-contact layer.

7. The semiconductor light emitting device of claim 6, wherein the highly reflective ohmic-contact layer includes a material selected from the group consisting of silver (Ag), nickel (Ni), aluminum (Al), rhodium (Rh), palladium (Pd), iridium (Ir), ruthenium (Ru), magnesium (Mg), zinc (Zn), platinum (Pt), gold (Au), and a combination thereof.

8. The semiconductor light emitting device of claim 1, wherein the at least one contact hole is a plurality of contact holes.

9. The semiconductor light emitting device of claim 1, wherein the first region of the semiconductor laminate has an area larger than that of the second region of the semiconductor laminate.

10. The semiconductor light emitting device of claim 9, wherein the second region of the semiconductor laminate has an area less than or equal to 20% of the entire area of the semiconductor laminate.

11. A light emitting diode (LED) module comprising:
a semiconductor light emitting device; and
a package substrate having first and second electrode structures,
wherein the semiconductor light emitting device comprises:
a semiconductor laminate having a first main surface provided by a first conductivity-type semiconductor layer and a second main surface provided by a second conductivity-type semiconductor layer, wherein the first and second main surfaces are opposed to each other, an active layer is formed between the first and second conductivity-type semiconductor layers, and the laminate is divided into first and second regions by a separation groove;
at least one contact hole connected to a portion of the first conductivity-type semiconductor layer through the active layer from the second main surface of the first region;
a first electrode formed on the second main surface of the semiconductor laminate, connected to the first conductivity-type semiconductor layer of the first region through the at least one contact hole and connected to the second conductivity-type semiconductor layer of the second region;
a second electrode formed on the second main surface of the first region and connected to the second conductivity-type semiconductor layer of the first region;
a first electrode pad electrically connected to the first conductivity-type semiconductor layer of the second region;
a second electrode pad electrically connected to the second electrode; and
a support substrate having electrical conductivity formed on the second main surface of the semiconductor laminate so as to be electrically connected to the first electrode, and
wherein the first electrode structure is connected to the support substrate of the semiconductor light emitting device and the second electrode structure is connected to the first and second electrodes of the semiconductor light emitting device, respectively.

12. The LED module of claim 11, further comprising an insulating separation layer formed on the second main surface of the semiconductor laminate to separate the first electrode and the second electrode.

13. The LED module of claim 12, wherein the insulating separation layer extends between inner side walls of the contact hole and a portion of the first electrode charged in the contact hole.

14. The LED module of claim 11, wherein the support substrate is formed through a plating process or a wafer bonding process.

15. The LED module of claim 11, further comprising: a passivation layer formed on lateral surfaces of the first and second regions of the semiconductor laminate.

16. The LED module of claim 11, wherein the first electrode includes a highly reflective ohmic-contact layer.

17. The LED module of claim 16, wherein the highly reflective ohmic-contact layer includes a material selected from the group consisting of silver (Ag), nickel (Ni), aluminum (Al), rhodium (Rh), palladium (Pd), iridium (Ir), ruthenium (Ru), magnesium (Mg), zinc (Zn), platinum (Pt), gold (Au), and a combination thereof.

18. The LED module of claim 11, wherein the at least one contact hole is a plurality of contact holes.

19. The LED module of claim 11, wherein the first region of the semiconductor laminate has an area larger than that of the second region of the semiconductor laminate.

20. The LED module of claim 19, wherein the second region of the semiconductor laminate has an area less than or equal to 20% of the entire area of the semiconductor laminate.
